(19) United States
(12) Patent Application Publication
(10) Pub. No.: US 2009/0217966 A1
(43) Pub. Date: Sep. 3, 2009

(54) THIN-FILM TYPE SOLAR CELL INCLUDING BY-PASS DIODE AND MANUFACTURING METHOD THEREOF

(75) Inventors: Young-Joo Eo, Seoul (KR); Hwa-Nyeon Kim, Seoul (KR); Seh-Won Ahn, Seoul (KR); Hae-Seok Lee, Seoul (KR); Heon-Min Lee, Seoul (KR); Jung-Heum Yun, Seoul (KR); Kwang-Sun Ji, Seoul (KR); Bum-Sung Kim, Seoul (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 12/295,712

(22) PCT Filed: Sep. 3, 2007
(86) PCT No.: PCT/KR2007/004238

§ 371 Date: Mar. 16, 2009

(30) Foreign Application Priority Data
Sep. 4, 2006 (KR) 10-2006-0084836

(51) Int. Cl. H01L 27/142; H01L 31/18; H01L 31/09

(52) U.S. Cl. 136/244; 438/73; 257/E21.158; 257/E27.124; 257/E31.093

(57) ABSTRACT

The present invention relates to a photovoltaic conversion apparatus including a by-pass diode and a manufacturing method thereof. The photovoltaic conversion apparatus of the present invention comprises at least one unit solar cell module configured of at least one unit solar cell; and a by-pass solar cell module including at least one solar cell electrically connected to the unit solar cell to by-pass current.

According to the present invention, a photovoltaic conversion apparatus having high photoelectric conversion efficiency can be manufactured. Also, the photovoltaic conversion apparatus will contribute to earths environmental conservation as the next clean energy source and can be directly applied to private facilities, public facilities, military facilities, etc., to create enormous economic value.

### TECHNICAL FIELD

The present invention relates to a photovoltaic conversion apparatus including a by-pass diode and a manufacturing method thereof.

More specifically, the present invention relates to a structure of a solar cell module including a solar cell including a by-pass diode and a manufacturing method thereof for overcoming problems of current limitation and hot spot generation due to the solar cell generating less photocurrent.

### BACKGROUND ART

The outlook for fossil fuels that we are now been using is discouraging. In 2003, British Petroleum (BP), an oil refining company of England, predicted that considering the fossil fuels in recoverable deposits, crude oil may be in use for about 40 years, natural gas for about sixty two years and coal for about two hundred and sixteen years. However, since big consumers of energy, such as China and India have appeared, it is expected to be shorter than these predicted periods. Also, when considering soaring crude oil costs, it can be assumed that these are not remote future events.

Therefore, the development of energy capable of replacing the fossil fuels is absolutely needed for the survival of humanity in the future.

A solar cell is a device that generates energy by converting light energy transferred from the sun to the earth into electrical energy. The development of the solar cell began from the technological development of growing single crystal silicon. The solar cell in various principles and structures is undergoing continuous development. Also, the oil shock in the 1970s, the severity of the greenhouse effect due to carbon dioxide highlighted in the early 1990s, and an international agreement to regulate carbon dioxide emissions for preventing global warming in the late 1990s serve as important lessons that teach humans the necessity of clean energy, such as solar power.

The development of the solar cell has been pursued in view of an improvement in photoelectric conversion efficiency, a reduction in manufacturing costs, and a large area solar cell. Therefore, the development of a thin-film type solar cell wherein amorphous silicon based materials are deposited on plate-shaped glass or metal in a multi-layer structure, instead of crystalline silicon, has been actively pursued. The amorphous silicon based thin-film type solar cell has a disadvantage that the photoelectric conversion efficiency is relatively low as compared to the crystalline silicon based solar cell; however, it has much more room for improving the photoelectric conversion efficiency and it has an advantage of reducing manufacturing costs by increasing production rate through large and automated deposition equipment.

FIGS. 1 to 7 show a manufacturing method of a photovoltaic conversion apparatus generally called a single junction cell, in particular, a thin-film type silicon based solar cell.

Referring to FIGS. 1 to 7, a transparent conductive layer 102 is deposited on an upper surface of a transparent substrate 101 (FIG. 2) and a patterning 102a is then performed on the transparent conductive layer 102 (FIG. 3). The direction of the patterning 102a is a longitudinal direction and as a method of performing the patterning 102a a laser scribing method is used. A photoelectric conversion layer 103 is deposited on the upper surface of the patterned transparent conductive layer 102 (FIG. 4) and a patterning 103a is performed on the photoelectric conversion layer to expose the transparent conductive layer 102 (FIG. 5). A backside electrode layer 104 is deposited on the upper surface of the patterned photoelectric conversion layer 103 (FIG. 6) and a patterning 104a is performed on the backside electrode layer 104 to expose the transparent conductive layer 102 (FIG. 7). FIG. 8 shows an equivalent circuit of the solar cell manufactured by FIGS. 1 to 7.

The problem in this structure is that since the solar cells are connected in series, the same amount of photocurrent should be generated in all the unit cells that are connected. If the same amount of photocurrent is not generated in the respective unit cells, the current is limited by means of the cells generating less photocurrent so that the photocurrent generated in the all the cells is reduced, thereby leading to a disadvantage in that the total efficiency of the solar cell module is degraded. Also, since the cells generating less photocurrent serve as the hot spot, heat is generated with the passage of time, so that there is a risk of destroying the devices.

The problem as described above occurs very frequently. The problem may occur in the case where the incidence of sunlight is interrupted by means of, for example, shadows of neighboring buildings, leaves, dust, etc., that cover a specific portion of the cell. Therefore, there should be manufactured a solar cell module including a by-pass diode to avoid the generation of a hot spot. However, it is difficult to manufacture the solar cell module in such a structure through the conventional manufacturing method of the thin-film type module.

### DISCLOSURE

### Technical Problem

The present invention proposes to solve the problems as described above. It is an object of the present invention to provide a photovoltaic conversion apparatus including a by-pass diode and a manufacturing method for overcoming problems of current limitation and hot spot generation due to a solar cell generating less photocurrent.

### Technical Solution

In order to accomplish the objects, there is provided a photovoltaic conversion apparatus of the present invention comprising: at least a one unit solar cell module configured of at least a one unit solar cell; and a by-pass solar cell module including at least one solar cell electrically connected to the unit solar cell to by-pass current.

In the present invention, the unit solar cell and the by-pass solar cell can be electrically connected through a conductive layer.

In the present invention, the by-pass solar cell electrically connected to the unit solar cell to by-pass current is not positioned on the same line as the unit solar cell in up, down, left, and right directions.

In the present invention, the unit solar cell and the solar cell electrically connected to the unit solar cell to by-pass current may be made of the same material and have the same structure, but may have different material or structure.

In the present invention, each solar cell constituting the unit solar cell module and the bypass solar cell module preferably has the same material and structure, but is not necessarily limited thereto.

In the present invention, the unit solar cell and the bypass solar cell respectively include a conductive layer, a photoelectric conversion layer, and a backside electrode layer, which are sequentially stacked on a substrate.

The conductive layer may be a transparent electrode or a metal electrode.

The transparent electrode is preferably one material selected from ZnO, SnO₂, and ITO. In the present invention, the photoelectric conversion layer constituting the unit solar cell and the photoelectric conversion layer constituting the bypass solar cell may be the same or not the same.

The photoelectric conversion layer may be constituted by one thin film selected from a silicon semiconductor thin film, a compound semiconductor thin film, and an organic type thin film and may be constituted by a single junction layer or a hetero junction layer, but is not necessarily limited thereto.

The photoelectric conversion layer may be stacked in any one form of a p-n single junction, a p-i-n single junction, multiple p-n single junction, multiple p-i-n single junction, and a mixed junction with the p-n single junction layer and the p-i-n single junction layer.

The photoelectric conversion layer with the multiple junction and the photoelectric conversion layer with the mixed junction further comprise a transparent electrode layer between the respective photoelectric conversion layers with single junction.

In the present invention, the substrate may be a transparent substrate or an opaque substrate and may be a glass substrate or an insulation substrate.

In the present invention, at least one of the conductive layer and the backside electrode layer may be formed of the transparent electrode.

The backside electrode layer is preferably any one of a transparent conductive oxide layer, a metal single layer, and a mixed layer of a transparent conductive oxide layer and a metal layer.

The transparent conductive oxide layer may be formed of one or more material selected from ZnO, SnO₂, and ITO.

In order to accomplish the objects, there is provided a manufacturing method of a photovoltaic conversion apparatus of the present invention comprising the steps of: stacking a photoelectric conversion layer on an upper surface of a conductive layer patterned in a predetermined direction; patterning the photoelectric conversion layer so that at least one unit solar cell module configured of at least one unit solar cell and a by-pass solar cell module including at least one solar cell electrically connected to the unit solar cell to by-pass current are formed; stacking a backside electrode layer on the upper of the patterned photoelectric conversion layer; and patterning the backside electrode layer in the same direction as the patterned direction of the photoelectric conversion layer.

In the step of patterning the photoelectric conversion layer and the backside electrode layer, the patterning can be performed so as to expose a part of the conductive layer. In the present invention, as the patterning methods may be one method selected from the group of a laser scribing method, a mechanical scribing method, and a photolithography method. The photolithography method may consist of a photoresist process, an exposure process, and an etching process.

In order to accomplish the objects, there is provided a manufacturing method of a photovoltaic conversion apparatus of the present invention comprising the steps of: forming a unit solar cell module by arranging at least one unit solar cell constituted by a photoelectric conversion layer and a backside electrode layer on an upper surface of a conductive layer; and forming a by-pass solar cell module including at least one solar cell electrically connected to the unit solar cell to by-pass current on the upper surface of the conductive layer.

In the present the by-pass solar cell may be the same or not the same as the unit solar cell. That is, the material, stack structure, and shape, etc., which constitute these solar cells, may be the same or not the same.

In the present invention, the photoelectric conversion layer may be a single junction layer or a hetero junction layer of a silicon semiconductor thin film or a compound semiconductor thin film.

In the present invention, the unit solar cell module may be defined by an aggregate constituted by at least one unit solar cell.

Also, the by-pass solar cell is capable of by-passing current by changing current flow when a particular solar cell is destroyed due to thermal overload caused by occurrence of a hot spot.

The by-pass solar cell module may be defined by an aggregate including at least one solar cell performing such a by-pass function.

### ADVANTAGEOUS EFFECTS

According to the present invention, a photovoltaic conversion apparatus having high photoelectric conversion efficiency can be manufactured.

Also, the photovoltaic conversion apparatus will contribute to earths environmental conservation as the next clean energy source and can be directly applied to private facilities, public facilities, military facilities, etc., to create enormous economic value.

### DESCRIPTION OF DRAWINGS

FIGS. 1 to 7 show a manufacturing method of a thin-film type silicon based solar cell generally called a single junction cell;

FIG. 8 is an equivalent circuit diagram of the solar cell manufactured by means of FIGS. 1 to 7;

FIGS. 9 to 15 show a manufacturing process of a thin-film type solar cell including a by-pass diode according to one embodiment of the present invention;

FIG. 16 is an equivalent circuit diagram of the thin-film type solar cell manufactured by means of FIGS. 9 to 15; and

FIGS. 17 to 20 show a general situation in a solar cell module proposed in a prior art and a solar cell module proposed in the present invention and current flow when a hot spot is generated.

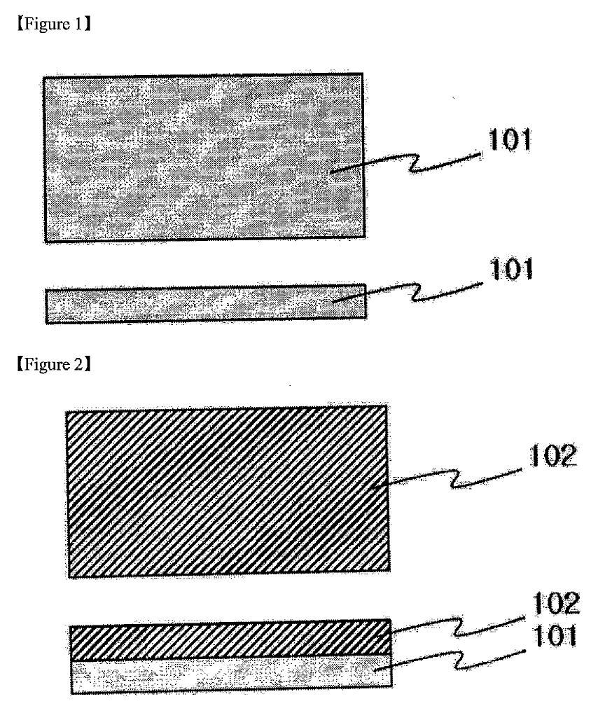

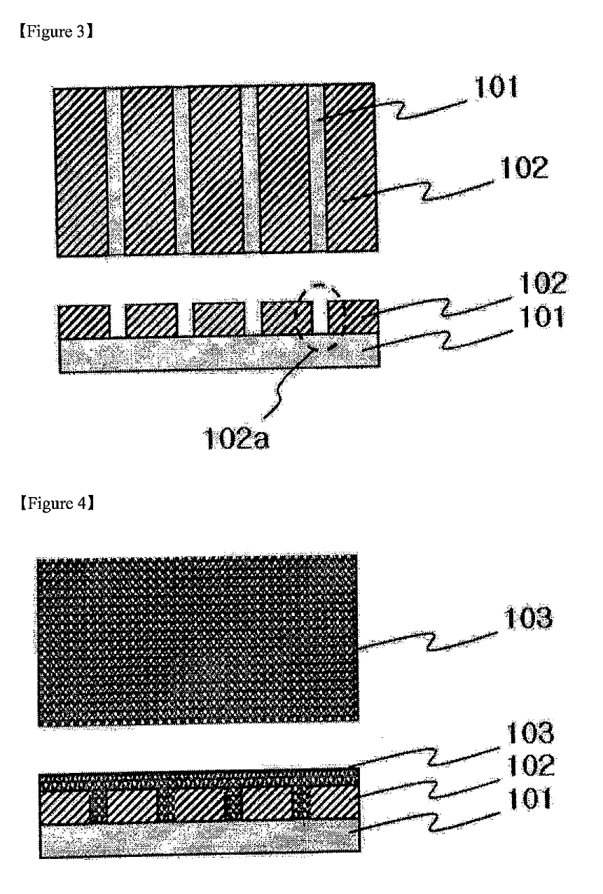

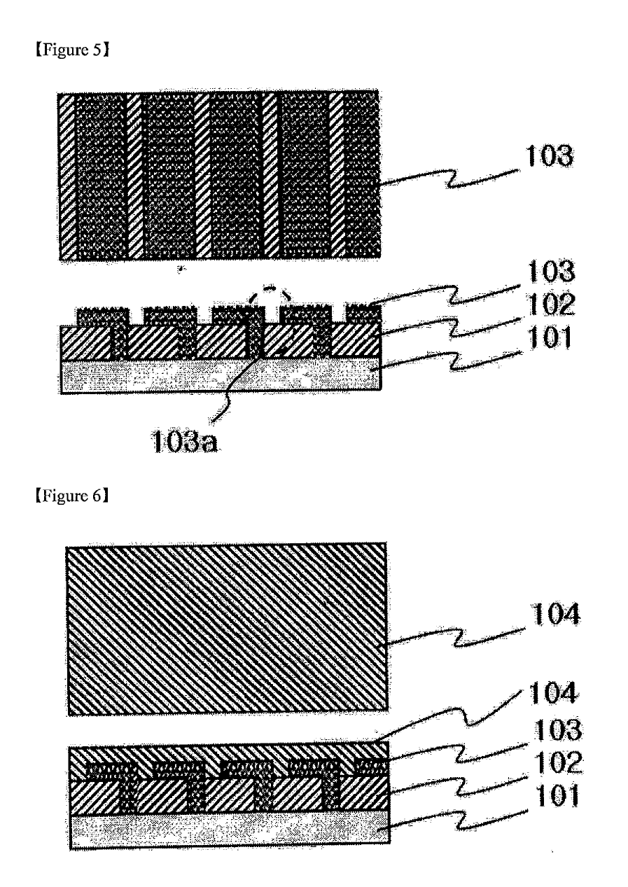

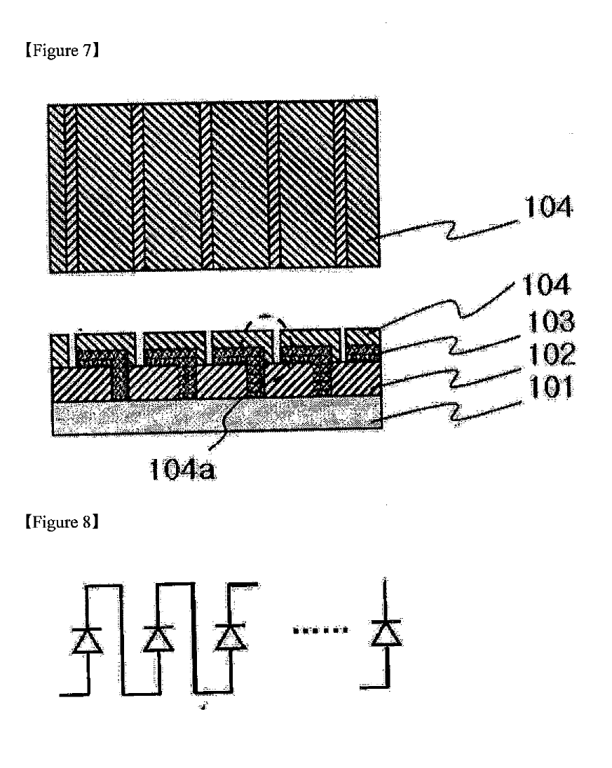

### DESCRIPTION FOR KEY ELEMENTS IN THE DRAWINGS

301: Transparent substrate 302: Transparent conductive layer
303: Photoelectric conversion layer 304: Backside electrode layer
305: Upper photoelectric conversion layer pattern
306: Lower photoelectric conversion layer pattern

### BEST MODE

Hereinafter, the preferred embodiments of the present invention will be described with reference to the accompanying drawings. In indicating the reference numerals and signs for components throughout the following drawings, although the same components are shown in different drawings, they will be indicated by the same reference numerals and signs. A detailed description of known functions and configurations will be omitted so as not to obscure the subject of the present invention with unnecessary detail.

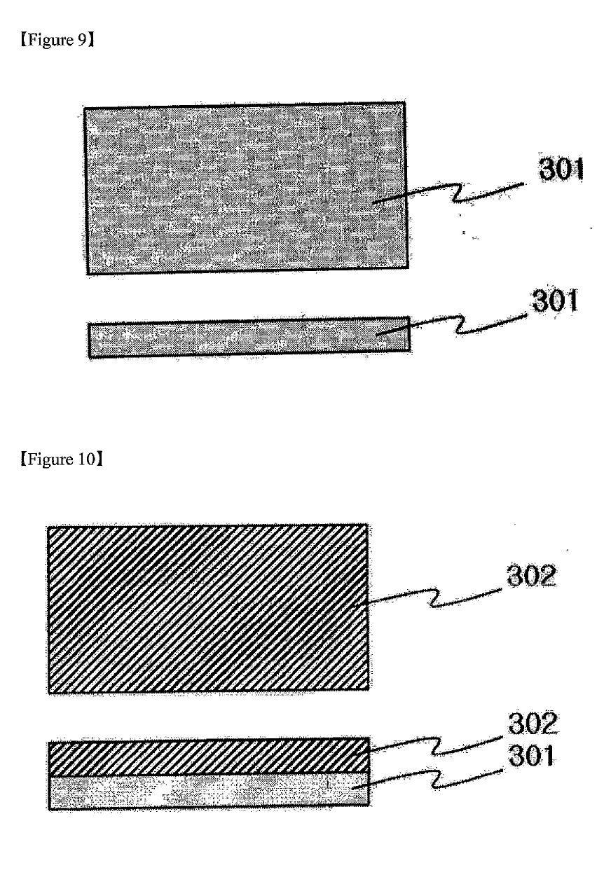

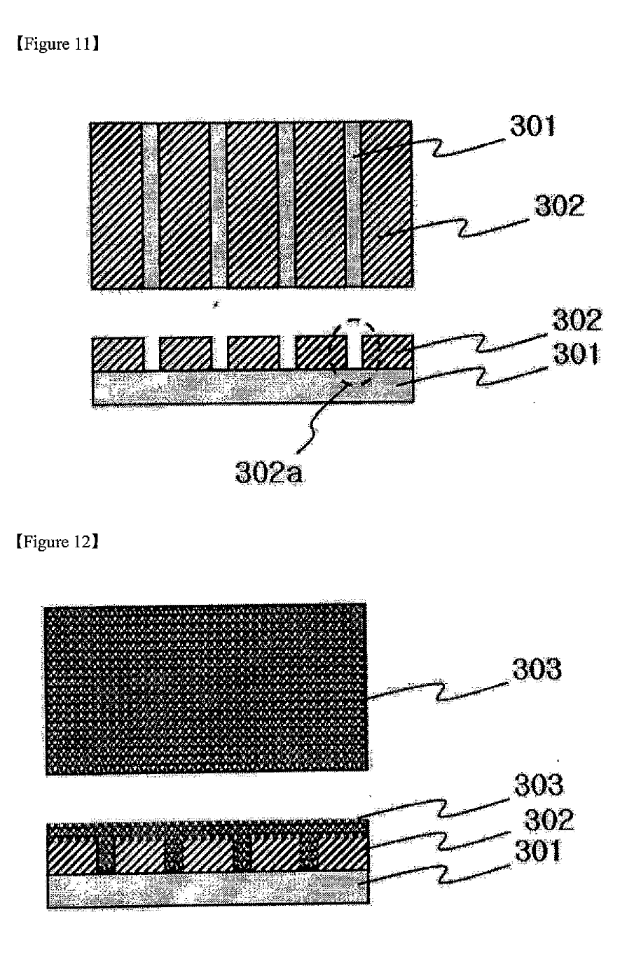

FIGS. 9 to 15 show a manufacturing process of a photovoltaic conversion apparatus including a by-pass diode according to one embodiment of the present invention, in particular, a thin-film type solar cell. Hereinafter, as a concrete embodiment of the photovoltaic conversion apparatus of the present invention, the thin-film type solar cell will be described.

The manufacturing method of the thin-film type solar cell of the present invention will be described below with reference to FIGS. 9 to 15.

FIGS. 9 to 12 show a process that deposits a transparent conductive layer 302 on a transparent substrate 301 and patterns 302a the transparent conductive layer 302, and then stacks a photoelectric conversion layer 303 thereon. The manufacturing process of the solar cell is the same as the prior art and a detailed description thereof will thus be omitted.

With one embodiment of the present invention according to the FIGS. 9 to 15, two unit solar cell modules are considered.

The respective unit solar cell modules are constituted by a plurality of unit solar cells that are arranged in a row.

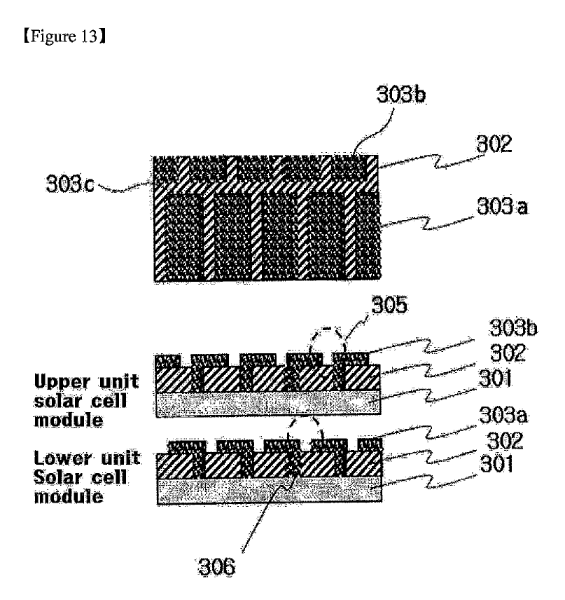

FIG. 13 shows a process of patterning the photoelectric conversion layer 303. First, the patterning that partitions the photoelectric conversion layer 303 into two unit solar cell modules is performed.

In other words, the patterning 303c that partitions the photoelectric conversion layer into an upper unit solar cell module 303b and a lower unit solar cell module 303a is performed. The patterning may be performed in left and right directions in order to partition the photoelectric conversion layer into the upper unit solar cell module and the lower unit solar cell module.

In order to form the unit solar cells within the unit solar cell modules partitioned up and down, each of the photoelectric conversion layers corresponding to the upper and lower unit solar cell modules is patterned. The patterning for forming the unit solar cells may be performed up and down.

However, the unit solar cell in the upper unit solar cell module and the neighboring unit solar cell in the lower unit solar cell module are alternately formed so that they are not positioned on the same line.

To this end, when patterning up and down in order to form the unit solar cells in the upper unit solar cell module and when patterning up and down in order to form the unit solar cells in the lower unit solar cell module, the unit solar cells should be alternated so as not to be directly alongside each other.

The unit solar cells in the upper solar cell module patterned in such a manner can be operated as the by-pass solar cells capable of by-passing current when some unit solar cells hi the lower unit solar cell module are destroyed or do not operate.

Conversely, when particular unit solar cells in the upper unit solar module are destroyed, the unit solar cells in the lower unit solar module can function as the by-pass solar cells. The photoelectric conversion layer 303 may be a single junction solar cell diode constituted by p-type semiconductor/i-type semiconductor/n-type semiconductor layer (or p-type semiconductor/n-type semiconductor) and a stacked solar cell diode where a plurality of single junction solar cell diodes are connected in series or in parallel. Also, in a process of forming a stacked solar cell, a transparent electrode layer as an intermediate layer may be inserted between the single junction solar cell diodes.

The semiconductor layer constituting the photoelectric conversion layer may be a silicon thin film, a compound semiconductor thin film, or an organic type semiconductor thin film.

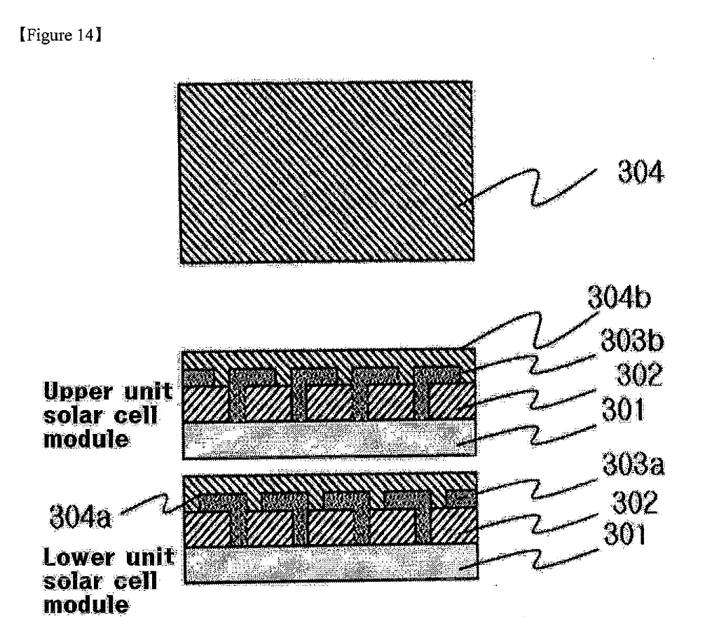

FIG. 14 shows a process of depositing a backside electrode layer 304, the backside electrode layer 304 being deposited on the upper surface of the patterned photoelectric conversion layer 303.

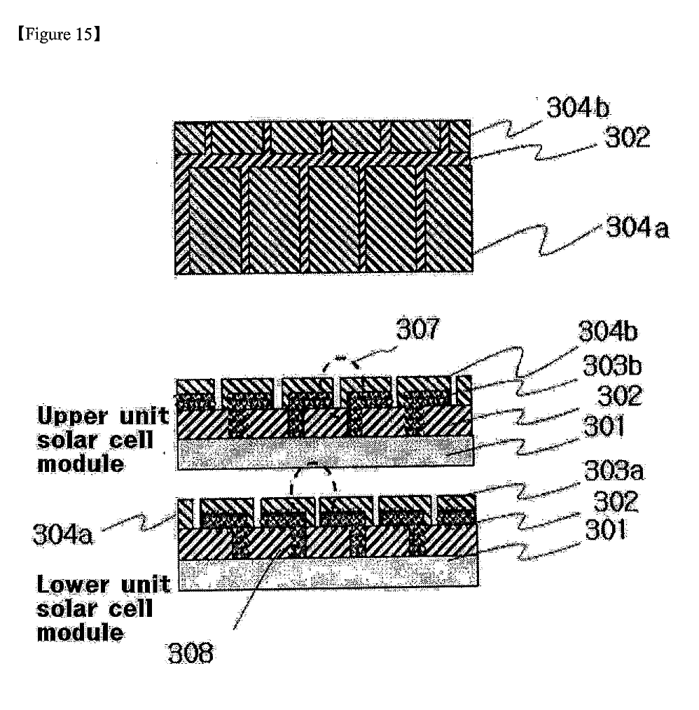

The backside electrode layer 304 may be formed of a transparent conductive oxide, a single layer of metal, or a multi-layer of the transparent conductive oxide and the metal. FIG. 15 shows a process of patterning the backside electrode layer 304, the backside electrode layer 304 being patterned to a depth that the transparent conductive layer 302 is exposed. The patterning that partitions the backside electrode layer into the upper unit solar cell module 304b and the lower unit solar cell module 304a is performed. Each of the solar cell modules that are partitioned into the upper and lower unit solar cell modules is patterned up and down.

The patterning positions in a longitudinal direction, which are formed at each of the upper and lower solar cell modules of the backside electrode layer 304, are preferably formed at alternate positions so as not to be directly alongside each other, as in the patterning of the photoelectric conversion layer 303.

As the patterning method, a method known to those skilled in the art such as a laser scribing method, a mechanical scribing method, and a photolithography method. The photolithography method may consist of a photoresist process, an exposure process, and an etching process.

The embodiment shown in FIGS. 9 to 15 describes the manufacturing method of the thin-film type solar cell. The solar cell of the present invention is not limited to the thin-film type.

The substrate 301 may be a transparent substrate, preferably a glass substrate, but may use a layer where an insulation layer is stacked on a polymer, a metal, or a stainless steel.

The transparent conductive layer 302 can be replaced with a metal electrode. However, in case that the transparent conductive layer 302 is replaced with the metal electrode, the backside electrode layer should be formed of a transparent electrode to transmit light from the outside.

The photoelectric conversion layer 303 can also be replaced with another photoelectric conversion layer other than the silicon p-i-n thin film. As the photoelectric conversion layer, a compound type p-n thin film or an organic type thin film may be used. The photoelectric layer is a constitution known to those skilled in the art and a detailed description thereof will thus be omitted so as not to obscure the subject of the present invention.

Therefore, the solar cell of the present invention can use the transparent substrate or the insulation substrate as the substrate and the transparent electrode and the metal electrode as the transparent conductive layer and the backside electrode layer. However, at least one of the transparent conductive layer and the backside conductive layer should be formed of a transparent conductive material. The photoelectric conversion layer can also use one of known photoelectric conversion layers.

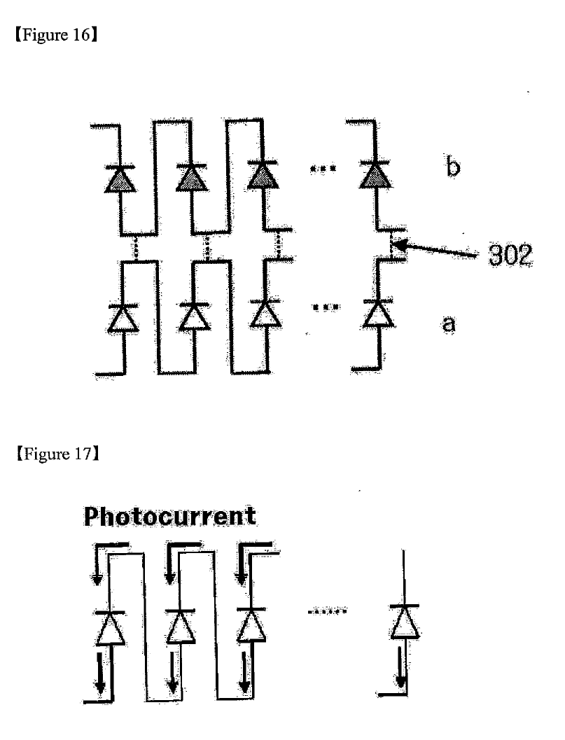

In the thin-film type solar cell manufactured through the aforementioned process, its plane is partitioned into two unit solar cell modules. The upper unit solar cell module is the by-pass solar cell module including the by-pass diode of the present invention and the lower unit solar cell module is the solar cell layer. The equivalent circuit of the thin-film type solar cell formed through the aforementioned process is the same as that shown in FIG. 16.

Referring to FIG. 16, the equivalent circuit of the lower unit solar cell module is the same as that of an existing solar cell, and there are by-pass diodes above the lower unit solar cell module, each by-pass diode being connected by means of the transparent conductive layer.

If a hot spot is generated in the unit solar cell at the lower unit solar cell module, current may flow into the by-pass diodes at the upper unit solar cell module so that the reduction in efficiency may be less and the stability of the present invention, the photovoltaic conversion apparatus may be improved.

FIGS. 17 to 20 show a current flow in a solar cell module proposed in a prior art and a solar cell module proposed in the present invention when a hot spot is generated.

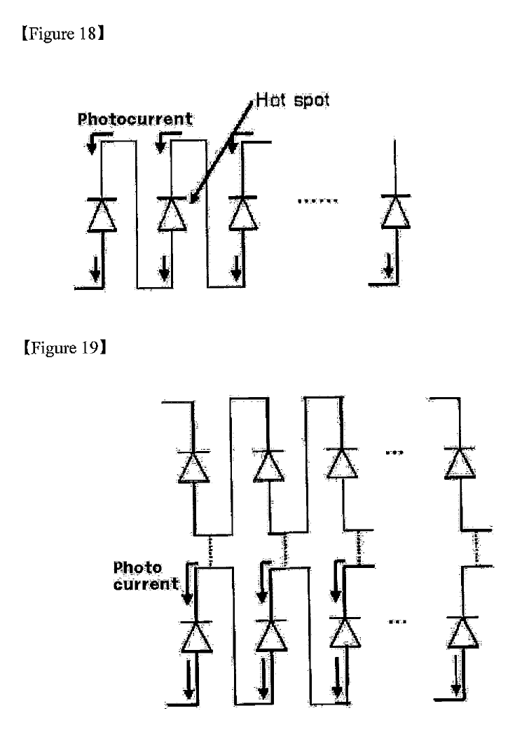

FIG. 17 is an equivalent circuit of an conventional thin-film type solar cell, wherein in the case of a conventional solar cell, current flows from right to left. In this case, when a hot spot is generated in predetermined portion of the solar cell as in FIG. 18, since there is no solution, heat is generated such that the device could be destroyed.

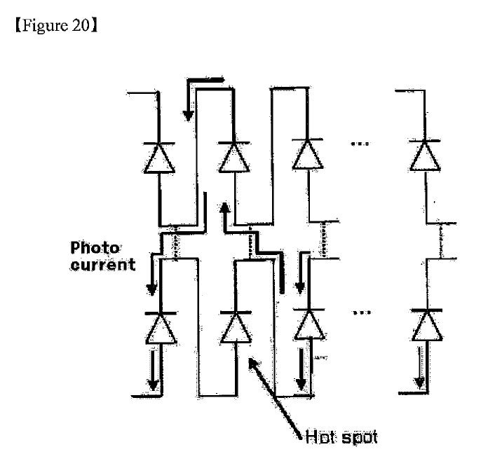

FIG. 19 is an equivalent circuit of a thin-film type solar cell according to the present invention, wherein the by-pass diodes are connected to each thin-film type solar cell. Generally, when a hot spot is not generated, current flows only at the lower unit solar cell module; however, as in FIG. 20, when a hot spot is generated in a part of the solar cell, current does not pass through the cell having a portion where the hot spot is generated but passes through the by-pass diode connected to the cell so that the influence of the hot spot is removed.

Although a few embodiments of the present invention have been shown and described, it would be appreciated by those skilled in the art that changes might be made in this embodiment without departing from the principles and spirit of the invention, the scope of which is defined in the claims and their equivalents.

### INDUSTRIAL APPLICABILITY

According to the present invention, a photovoltaic conversion apparatus having high photoelectric conversion efficiency can be manufactured. Also, the photovoltaic conversion apparatus will contribute to earths environmental conservation as the next clean energy source and can be directly applied to private facilities, public facilities, military facilities, etc., to create enormous economic value.

1. A photovoltaic conversion apparatus including a by-pass solar cell module comprising:
at least one unit solar cell module configured of at least one unit solar cell; and
a by-pass solar cell module including at least one solar cell electrically connected to the unit solar cell to by-pass current.

2. The photovoltaic conversion apparatus of claim 1, wherein the unit solar cell and the by-pass solar cell are electrically connected through a conductive layer.

3. The photovoltaic conversion apparatus of claim 1, wherein the by-pass solar cell electrically connected to the unit solar cell to by-pass current is not positioned on the same line as the unit solar cell in up, down, left, and right directions.

4. The photovoltaic conversion apparatus of claim 1, wherein the unit solar cell and the by-pass solar cell respectively include a conductive layer, a photoelectric conversion layer, and a backside electrode layer, which are sequentially stacked on a substrate.

5. The photovoltaic conversion apparatus of claim 2 or 4, wherein the conductive layer is a transparent electrode or a metal electrode.

6. The photovoltaic conversion apparatus of claim 5 wherein the transparent electrode is one material selected from ZnO, SnO₂, and ITO.

7. The photovoltaic conversion apparatus of claim 4, wherein the photoelectric conversion layer constituting the unit solar cell and the photoelectric conversion layer constituting the bypass solar cell are the same or not the same.

8. The photovoltaic conversion apparatus of claim 4 or 7, wherein the photoelectric conversion layer is constituted by one thin film selected from a silicon semiconductor thin film, a compound semiconductor thin film, and an organic type thin film.

9. The photovoltaic conversion apparatus of claim 4 or 7, wherein the photoelectric conversion layer is stacked in any one form of a p-n single junction, a p-i-n single junction, multiple p-n single junction, multiple p-i-n single junction, and a mixed junction with the p-n single junction layer and the p-i-n single junction layer.

10. The photovoltaic conversion apparatus of claim 9, wherein the photoelectric conversion layer with the multiple junction and the photoelectric conversion layer with the mixed junction further comprise a transparent electrode layer between the respective photoelectric conversion layers with single junction.

11. The photovoltaic conversion apparatus of claim 4, wherein the substrate is a transparent substrate or an opaque substrate.

12. The photovoltaic conversion apparatus of claim 4, wherein the substrate is a glass substrate or an insulation substrate.

13. The photovoltaic conversion apparatus of claim 4, wherein at least one of the conductive layer and the backside electrode layer is formed of the transparent electrode.

14. The photovoltaic conversion apparatus of claim 4, wherein the backside electrode layer is any one of a transparent conductive oxide layer, a metal single layer, and a mixed layer of a transparent conductive oxide layer and a metal layer.

15. The photovoltaic conversion apparatus of claim 14, wherein the transparent conductive oxide layer is formed of one or more material selected from ZnO, SnO₂, and ITO.

16. A manufacturing method of a photovoltaic conversion apparatus comprising the steps of:
stacking a photoelectric conversion layer on an upper surface of a conductive layer patterned in a predetermined direction;
patterning the photoelectric conversion layer so that at least one unit solar cell module configured of at least one unit solar cell and a by-pass solar cell module including at least one solar cell electrically connected to the unit solar cell to by-pass current are formed;
stacking a backside electrode layer on the upper surface of the patterned photoelectric conversion layer; and
patterning the backside electrode layer in the same direction as the patterned direction of the photoelectric conversion layer.

17. The method of claim 16, wherein in the step of patterning the photoelectric conversion layer and the backside electrode layer, the patterning is performed so as to expose a part of the conductive layer.

18. The method of claim 16, wherein the patterning methods are one method selected from the group of a laser scribing method, a mechanical scribing method, and a photolithography method.

19. A manufacturing method of a photovoltaic conversion apparatus comprising the steps of:
forming a unit solar cell module by arranging at least one unit solar cell constituted by a photoelectric conversion layer and a backside electrode layer on an upper surface of a conductive layer; and
forming a by-pass solar cell module including at least one solar cell electrically connected to the unit solar cell to by-pass current on the upper surface of the conductive layer.

20. The method claim 19, wherein the by-pass solar cell is the same or not the same as the unit solar cell.
